(19) United States
(12) Patent Application Publication
(10) Pub. No.: US 2006/0143551 A1
(43) Pub. Date: Jun. 29, 2006

(54) Localizing error detection and recovery

(75) Inventors: Arijit Biswas, Holden, MA (US); Steven E. Raasch, Shrewsbury, MA (US); Shubhendu S. Mukherjee, Framingham, MA (US); Subhasish Mitra, Rancho Cordova, CA (US)

Correspondence Address: TROP PRUNER & HU, PC, 8554 KATY FREEWAY, SUITE 100, HOUSTON, TX, 77024, US

(73) Assignee: Intel Corporation

(21) Appl. No.: 11/026,220

(22) Filed: Dec. 29, 2004

(51) Int. Cl. G01R 31/28

(52) U.S. Cl. 714/726

(57) ABSTRACT

In one embodiment, the present invention includes a method of detecting and correcting an error by detecting the error in a circuit coupled to a first stage of a semiconductor device, and correcting the error in the circuit using valid data present in the circuit. The circuit may be a scan cell, in some embodiments. In such manner, errors may be corrected locally, minimizing the impact of the error on performance and power consumption. Other embodiments are described and claimed.

### BACKGROUND

Embodiments of the present invention relate generally to error detection and/or correction in a semiconductor device.

Single bit upsets or errors from transient faults have emerged as a key challenge in semiconductor design. These faults arise from energetic particles, such as neutrons from cosmic rays and alpha particles from packaging material. These particles generate electron-hole pairs as they pass through a semiconductor device. Transistor source and diffusion nodes can collect these charges. A sufficient amount of accumulated charge may change the state of a logic device such as a static random access memory (SRAM) cell, a latch or a gate, thereby introducing a logical error into the operation of an electronic circuit. Because this type of error does not reflect a permanent failure of the device, it is termed a soft or transient error.

Soft errors become an increasing burden for designers as the number of on-chip transistors continues to grow. The raw error rate per latch or SRAM bit may be projected to remain roughly constant or decrease slightly for the next several technology generations. Thus, unless error protection mechanisms are added or more robust technology (such as fully-depleted silicon-on-insulator) is used, a semiconductor device's soft error rate may grow in proportion to the number of devices added in each succeeding generation. Additionally, aggressive voltage scaling may cause such errors to become significantly worse in future generations of chips.

Bit errors may be classified based on their impact and the ability to detect and correct them. Some bit errors may be classified as “false errors” because they are not read, do not matter, or can be corrected before they are used. The most insidious form of error is silent data corruption (“SDC”), where an error is not detected and induces the system to generate erroneous outputs. To avoid silent data corruption, designers often employ error detection mechanisms, such as parity. Error correction techniques such as error correcting codes (ECC) may also be employed to detect and correct errors, although such techniques cannot be applied in all situations. Furthermore, such error correction techniques consume semiconductor real estate, power, and processing time.

Scan cells are logic circuits added to a semiconductor device that are used during manufacturing testing and post-silicon debug of the device. The scan cells include flip-flops and contain logic to store and shift data out of a device's test output pins. The scan cells typically include a data path and a scan path. Typically, data can either be read out of a device using a scan cell or data can be transferred into a device to place a device into a known state. Scan cells are typically daisy-chained together to form one or more shift registers called a scan chain. These scan chains are primarily used to examine or set the state of the device during testing and debug operations. Typically, the scan portion of the scan cells are disabled prior to the device leaving the factory.

Accordingly, a need exists to more efficiently detect and correct errors within a semiconductor device.

### BRIEF DESCRIPTION OF THE DRAWINGS

FIG. 1 is a block diagram of an error recovery circuit in accordance with one embodiment of the present invention.

FIG. 2 is a block diagram of an error detection circuit in accordance with another embodiment of the invention.

FIG. 3 is a block diagram of a computer system with which embodiments of the invention may be used.

FIG. 4 is a block diagram of a multiprocessor system with which embodiments of the invention may be used.

### DETAILED DESCRIPTION

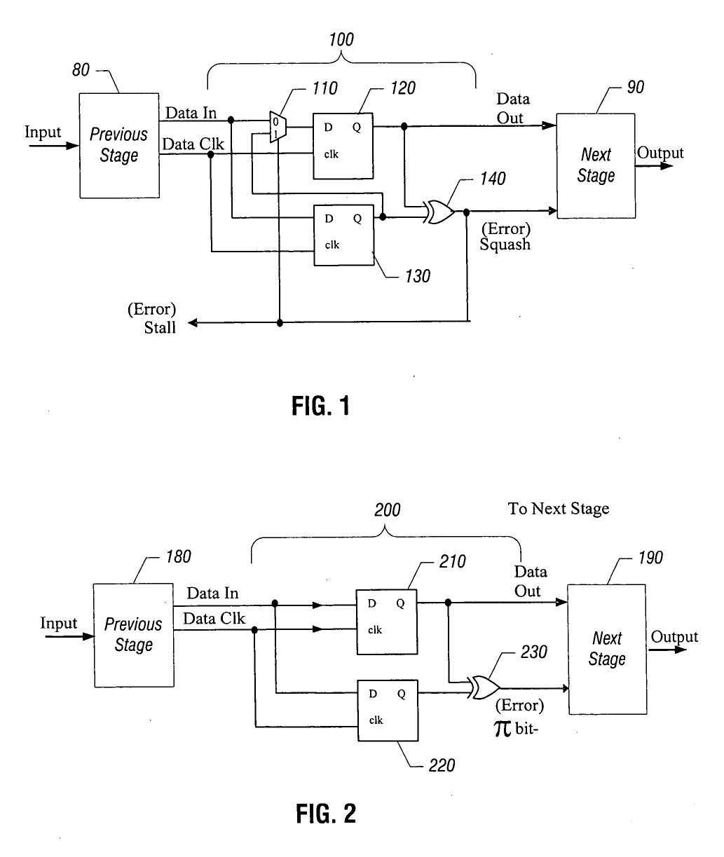

Referring to FIG. 1, shown is a block diagram of an error recovery circuit 100 in accordance with one embodiment of the present invention. While not limited in this regard, circuit 100 may be formed using a scan cell having redundancy that is unused during normal operation. In such manner, error recovery may be effected with minimal additional real estate consumption. That is, in some embodiments preexisting redundant state hardware may be leveraged to perform error detection and recovery with reduced hardware overhead.

As shown in FIG. 1, circuit 100 receives incoming data from a previous stage 80 as an incoming data signal, Data In. Previous stage 80 receives an input and may perform operations on the input to generate the incoming data. In one embodiment, previous stage 80 may be a processor pipeline stage such as an execution unit or the like. The incoming data is coupled to a multiplexer 110 and a second (or scan) flip-flop 130. In normal operation, multiplexer 110 passes the incoming data to a first (or data) flip-flop 120. Both flip-flops 120 and 130 are clocked by an incoming data clock signal, Data Clk. As shown in FIG. 1, the clock signal may also be provided by previous stage 80, although the scope of the present invention is not so limited. In various embodiments, second flip-flop 130 may be radiation hardened to ensure that data passing therethrough is valid (or at least highly resistant, if not immune to soft errors). For example, second flip-flop 130 may include larger or more transistors (and/or capacitors).

It is to be understood that the data and scan flip-flops shown in FIG. 1 may each be formed of multiple latches, such as multiple D-type or other such latches. While shown as being implemented with flip-flops, a data path circuit and a scan path circuit may be formed of other devices to store and pass along data.

Still referring to FIG. 1, the outputs of first flip-flop 120 and second flip-flop 130 are coupled to an exclusive-OR (XOR) logic gate 140. If the outputs of the flip-flops differ, XOR 140 generates an error signal that is provided to a next pipeline stage 90. Next stage 90 may be, in one embodiment, a processor pipeline stage such as floating point unit or the like.

The error signal may be used in next stage 90 to squash a data error. Furthermore, the error signal may be coupled to multiplexer 110 to cause the output of second flip-flop 130 to pass through to first flip-flop 120. In such manner, an error detected within circuit 100 may be corrected such that valid data is output from circuit 100. The error signal also may be provided to previous stage 80 to cause that stage to stall while error correction occurs in circuit 100.

Thus in operation, circuit 100 may be used to detect and correct an error, such as a single bit error caused by radiation, occurring in first flip-flop 120. Accordingly, when different values are output from flip-flops 120 and 130, the error signal is generated, in turn causing the faulty data value traveling to the next stage to be squashed, stalling the previous stage(s), and copying the valid data from second flip-flop 130 into first flip-flop 120. When the correct data is in place, the error signal may be removed, and the pipeline may continue to process data with a bubble (i.e., a squashed entry) where the faulty data was used. Accordingly, soft errors may be corrected as soon as they are detected, allowing recovery to occur locally, simplifying recovery and eliminating the need to replay work already completed successfully (e.g., the result of a previous stage).

In other embodiments, a hardened flip-flop need not be present in circuit 100. Error detection and correction may still occur by generating the error signal (as described above). This error signal when sent to the previous stage may cause that stage to regenerate and re-send the data, thereby correcting the error.

In yet other embodiments, soft errors may be detected and used to provide a control signal to indicate a possibly incorrect event. This control signal, which may be referred to as a π bit, may be used to reduce false errors and to trigger error recovery in other manners.

Referring now to FIG. 2, shown is a block diagram of an error detection circuit 200 in accordance with another embodiment of the invention. As shown in FIG. 2, circuit 200 may be a scan cell coupled between two pipeline stages (i.e., a previous stage 180 and a next stage 190). As shown in FIG. 2, circuit 200 includes a first flip-flop 210 and a second flip-flop 220, both coupled to receive incoming data, Data In and a data clock, Data Clk. In the embodiment of FIG. 2, both flip-flops 210 and 220 may be of the same general type. That is, in the embodiment of FIG. 2, second flip-flop 220 is not radiation hardened.

As further shown in FIG. 2, an XOR gate 230 is coupled to the outputs of the two flip-flops 210 and 220. During operation, if the outputs differ, XOR 230 generates an error signal, e.g., a π bit. This error signal may be provided to next stage 190 to indicate that the data output to the next stage is erroneous. The π bit may be used to trigger a recovery operation as appropriate in that stage or another location within a processor.

In such manner, scan cells may provide state bits that are closely associated with critical data values throughout a processor or other logic of an integrated circuit (IC). These state bits may form shift registers that allow error data to be extracted quickly. Using scan cells in accordance with an embodiment of the present invention, an error condition may be timely corrected, simplifying recovery and minimizing impact on performance and power consumption. Still further, an error signal may be generated and provided to later logic to inform the later logic (e.g., a later pipeline stage) that a recovery operation may be necessary.

By clocking multiple flip-flops within scan cells during normal operation, power consumption may be increased. Accordingly, in some embodiments an external control mechanism may be used to disable the error detection and/or correction mechanisms disclosed herein to reduce overall power consumption. As an example, a sensor may indicate that soft errors are unlikely to occur. For example, such a sensor may indicate that the system is being used in a location in which radiation and therefore soft errors are unlikely. Accordingly, the sensor may send a signal to disable at least the scan portions of the scan cells from performing error detection and/or correction. In other embodiments, a system setting may be used to indicate that power conservation is more important than error management and accordingly, the system setting may cause the scan cells to not perform error detection/correction.

Embodiments may be implemented in a computer program. As such, these embodiments may be stored on a storage medium having stored thereon instructions which can be used to program a system to perform the embodiments. The storage medium may include, but is not limited to, any type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic RAMs (DRAMs), erasable programmable read-only memories (EPROMs), electrically erasable programmable read-only memories (EEPROMs), flash memories, magnetic or optical cards, or any type of media suitable for storing electronic instructions. Similarly, embodiments may be implemented as software modules executed by a programmable control device, such as a computer processor or a custom designed state machine.

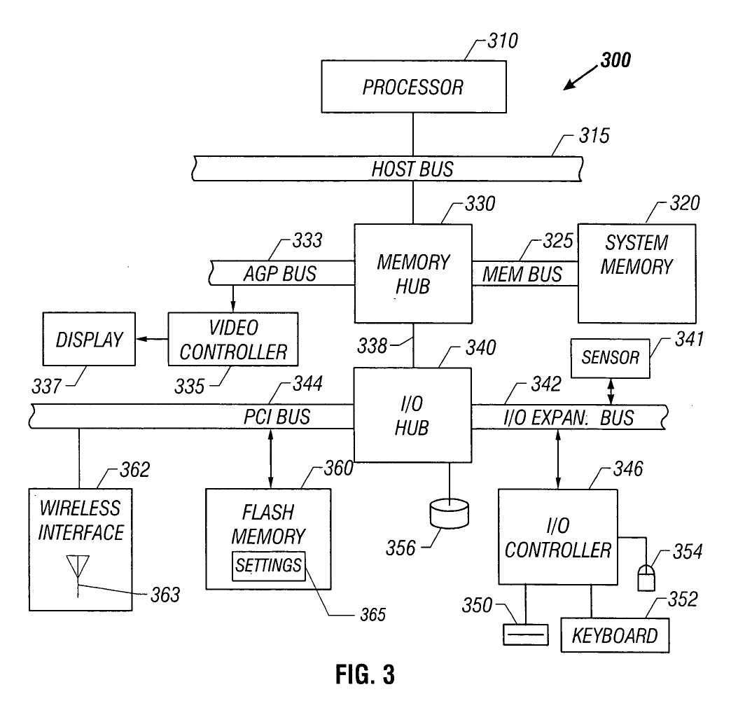

Referring now to FIG. 3, shown is a block diagram of a computer system 300 with which embodiments of the invention may be used. In one embodiment, computer system 300 includes a processor 310, which may include a general-purpose or special-purpose processor such as a microprocessor, microcontroller, application specific integrated circuit (ASIC), a programmable gate array (PGA), and the like. Processor 310 may include a plurality of scan cells configured such as those shown in FIGS. 1 and 2.

Processor 310 may be coupled over a host bus 315 to a memory controller hub (MCH) 330 in one embodiment, which may be coupled to a system memory 320 via a memory bus 325. In various embodiments, system memory 320 may be synchronous dynamic random access memory (SDRAM), static random access memory (SRAM), double data rate (DDR) memory and the like. Memory hub 330 may also be coupled over an Advanced Graphics Port (AGP) bus 333 to a video controller 335, which may be coupled to a display 337. AGP bus 333 may conform to the Accelerated Graphics Port Interface Specification, Revision 2.0, published May 4, 1998, by Intel Corporation, Santa Clara, Calif.

Memory hub 330 may also be coupled (via a hub link 338) to an input/output (I/O) controller hub (ICH) 340 that is coupled to a input/output (I/O) expansion bus 342 and a Peripheral Component Interconnect (PCI) bus 344, as defined by the PCI Local Bus Specification, Production Version, Revision 2.1 dated June 1995, or alternately a bus such as the PCI Express bus, or another third generation I/O interconnect bus.

I/O expansion bus 342 may be coupled to an I/O controller 346 that controls access to one or more I/O devices. As shown in FIG. 3, these devices may include in one embodiment storage devices, such as a floppy disk drive 350 and input devices, such as a keyboard 352 and a mouse 354. I/O hub 340 may also be coupled to, for example, a hard disk drive 356 as shown in FIG. 3. It is to be understood that other storage media may also be included in the system. In an alternate embodiment, I/O controller 346 may be integrated into I/O hub 340, as may other control functions.

As shown in FIG. 3, a sensor 341 may be coupled to I/O expansion bus 342. Sensor 341 may be used to sense that soft errors are unlikely to occur. For example, in one embodiment, sensor 341 may be a radiation sensor which senses an ambient amount of radiation in a given environment in which computer system 300 is operating. Data from sensor 341 may be provided to processor 310. If it is determined based on the sensor data that soft errors are unlikely to occur, processor 310 may cause scan cells or other error detection/correction circuitry within processor 310 or other chips of system 300 to be disabled to reduce power consumption. Alternately, at least the scan path circuits (e.g., flip-flop 130 of FIG. 1) may be disabled based on receipt of a sensor signal indicative of no radiation.

PCI bus 344 may be coupled to various components including, for example, a flash memory 360. As shown in FIG. 3, flash memory 360 may include storage for settings 365. Such settings may be associated with various system or user-selected control settings. For example, in one embodiment settings 365 may include a setting to indicate whether power consumption is more important than error management. If such a setting is indicated, system 300 may disable scan cells or other error detection/correction circuitry in processor 310 and/or other chips of system 300. In one embodiment, such settings may be implemented using a Basic Input/Output System (BIOS) stored in flash memory 360.

Further shown in FIG. 3 is a wireless interface 362 coupled to PCI bus 344, which may be used in certain embodiments to communicate wirelessly with remote devices. As shown in FIG. 3, wireless interface 362 may include a dipole or other antenna 363 (along with other components not shown in FIG. 3). While such a wireless interface may vary in different embodiments, in certain embodiments the interface may be used to communicate via data packets with a wireless wide area network (WWAN), a wireless local area network (WLAN), a BLUETOOTH™, ultrawideband, a wireless personal area network (WPAN), or another wireless protocol. In various embodiments, wireless interface 362 may be coupled to system 300, which may be a notebook or other personal computer, via an external add-in card or an embedded device. In other embodiments wireless interface 362 may be fully integrated into a chipset of system 300.

Although the description makes reference to specific components of the system 300, it is contemplated that numerous modifications and variations of the described and illustrated embodiments may be possible.

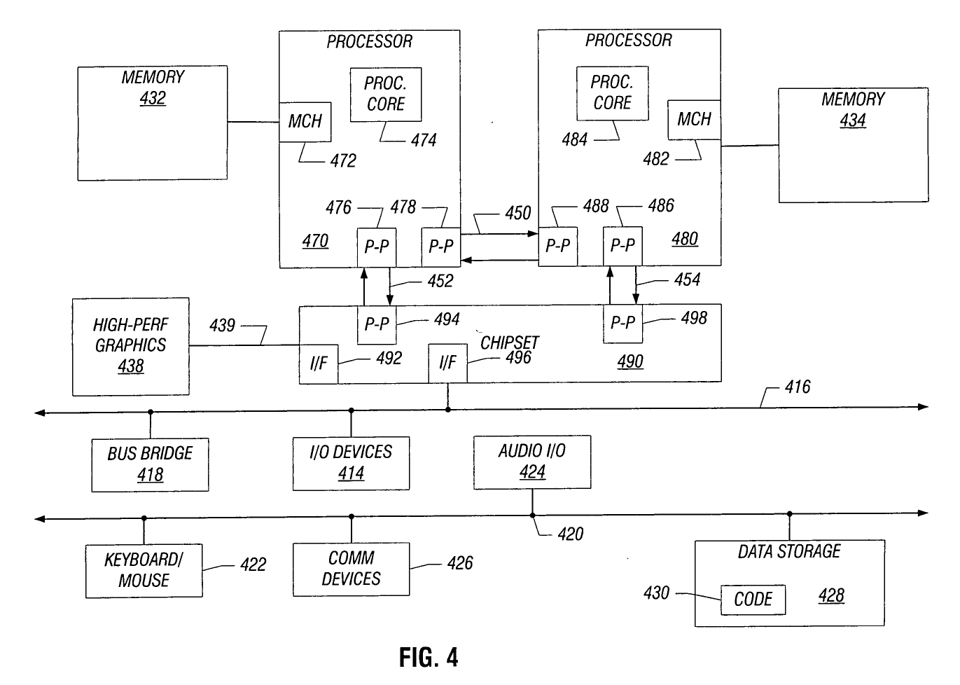

For example, other embodiments may be implemented in a multiprocessor system (e.g., a point-to-point bus system such as a common system interface (CSI) system). Referring now to FIG. 4, shown is a block diagram of a multiprocessor system in accordance with another embodiment of the present invention. As shown in FIG. 4, the multiprocessor system is a point-to-point bus system, and includes a first processor 470 and a second processor 480 coupled via a point-to-point interconnect 450. First processor 470 includes a processor core 474, a memory controller hub (MCH) 472 and point-to-point (P-P) interfaces 476 and 478. Similarly, second processor 480 includes the same components, namely a processor core 484, a MCH 482, and P-P interfaces 486 and 488. Processors 470 and 480 (and other circuitry within the system) may include error detection/correction circuitry in accordance with an embodiment of the present invention.

As shown in FIG. 4, MCH's 472 and 482 couple the processors to respective memories, namely a memory 432 and a memory 444, which may be portions of main memory locally attached to the respective processors. Each of memories 432 and 434 may include directories 434 and 436, respectively.

First processor 470 and second processor 480 may be coupled to a chipset 490 via P-P interfaces 452 and 454, respectively. As shown in FIG. 4, chipset 490 includes P-P interfaces 494 and 498. Furthermore, chipset 490 includes an interface 492 to couple chipset 490 with a high performance graphics engine 438. In one embodiment, an Advanced Graphics Port (AGP) bus 439 may be used to couple graphics engine 438 to chipset 490. AGP bus 439 may conform to the Accelerated Graphics Port Interface Specification, Revision 2.0, published May 4, 1998, by Intel Corporation, Santa Clara, Calif. Alternately, a point-to-point interconnect 439 may couple these components.

In turn, chipset 490 may be coupled to a first bus 416 via an interface 496. In one embodiment, first bus 416 may be a Peripheral Component Interconnect (PCI) bus, as defined by the PCI Local Bus Specification, Production Version, Revision 2.1, dated June 1995 or a bus such as the PCI Express bus or another third generation I/O interconnect bus, although the scope of the present invention is not so limited.

As shown in FIG. 4, various input/output (I/O) devices 414 may be coupled to first bus 416, along with a bus bridge 418 which couples first bus 416 to a second bus 420. In one embodiment, second bus 420 may be a low pin count (LPC) bus. Various devices may be coupled to second bus 420 including, for example, a keyboard/mouse 422, communication devices 426 and a data storage unit 428 which may include code 430, in one embodiment. Further, an audio I/O 424 may be coupled to second bus 420.

While described herein as primarily for use in connection with a processor, it is to be understood that in various embodiments error detection and/or correction using scan cells or other such circuitry may be implemented in various chips used in a system. For example, such scan cells may be implemented in a chipset associated with a processor, such as a MCH, an ICH, or other such circuitry. Furthermore, while described herein as being implemented within scan cells, it is to be understood that the scope of the present invention is not so limited, and error detection/correction circuitry may be implemented using latches or flip-flops apart from scan cells.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
detecting an error in a scan cell coupled to a first stage of a semiconductor device; and
correcting the error in the scan cell using valid data present in the scan cell.

2. The method of claim 1, further comprising storing the valid data in a hardened circuit within the scan cell.

3. The method of claim 1, further comprising detecting a soft error and correcting the error during normal operation of the semiconductor device.

4. The method of claim 1, further comprising generating an error signal indicative of the error.

5. The method of claim 4, further comprising sending the error signal to the first stage and a next stage of the semiconductor device.

6. The method of claim 5, further comprising squashing the error in the next stage using the error signal.

7. The method of claim 2, further comprising forwarding the valid data to a next stage of the semiconductor device.

8. The method of claim 7, further comprising forwarding the valid data under control of an error signal generated upon detecting the error.

9. The method of claim 1, further comprising disabling detecting the error and correcting the error.

10. The method of claim 1, further comprising disabling detecting the error and correcting the error based on a sensor signal.

11. An apparatus comprising:
a first circuit coupled to receive an output of a multiplexer, the first circuit to be clocked by a first clock; and
a second circuit to receive incoming data, the second circuit to be clocked by the first clock, the multiplexer to receive the incoming data and an output of the second circuit, the multiplexer to output the incoming data or the output of the second circuit.

12. The apparatus of claim 11, wherein the second circuit is radiation resistant.

13. The apparatus of claim 1 1, further comprising logic to receive an output of the first circuit and the output of the second circuit and to generate an error signal.

14. The apparatus of claim 11, wherein the apparatus comprises a scan cell.

15. The apparatus of claim 14, further comprising:
a previous processor pipeline stage to provide the incoming data to the scan cell; and
a next processor pipeline stage to receive an output of the scan cell.

16. The apparatus of claim 13, wherein the error signal to control the multiplexer.

17. The apparatus of claim 11, further comprising:
a sensor to sense radiation and generate a sensor signal; and
a controller to disable at least the second circuit based on the sensor signal.

18. A system comprising:
a processor having a first stage and a second stage;
an error circuit coupled between the first stage and the second stage to detect an error, the error circuit comprising:
a data path to receive an output of the first stage, the data path to be clocked by a first clock;
a scan path to receive the output of the first stage, the scan path to be clocked by the first clock; and
a dynamic random access memory coupled to the processor.

19. The system of claim 18, further comprising a multiplexer to receive the output of the first stage and an output of the scan path, the multiplexer to provide the output of the first stage or the output of the scan path to the data path.

20. The system of claim 18, wherein the error circuit comprises a scan cell of the processor.

21. The system of claim 19, further comprising logic to receive an output of the data path and the output of the scan path and to generate an error signal, wherein the error signal to cause the error circuit to output corrected data to the second stage.

22. The system of claim 21, wherein the error signal to cause the first stage to stall and the second stage to squash the error.

23. The system of claim 18, further comprising a storage to store a system setting, the system setting corresponding to a priority of power management and error management.

24. The system of claim 23, further comprising a controller to disable at least a portion of the error circuit based on the system setting.
